(19) United States
(12) Patent Application Publication
(10) Pub. No.: US 2026/0013258 A1
(43) Pub. Date: Jan. 8, 2026

(54) IMAGE SENSOR AND MANUFACTURING METHOD THEREOF

(71) Applicant: Samsung Electronics Co., Ltd., Suwon-si (KR)

(72) Inventor: Yoshiharu KUDO, Yokohama (JP)

(73) Assignee: Samsung Electronics Co., Ltd., Suwon-si (KR)

(21) Appl. No.: 19/241,269

(22) Filed: Jun. 17, 2025

(30) Foreign Application Priority Data
Jul. 4, 2024 (JP) 2024-108036
Mar. 7, 2025 (KR) 10-2025-0029951

(51) Int. Cl. H10F 39/00; H10D 30/62; H10D 80/20; H10F 30/225; H10F 39/10

(52) U.S. Cl. CPC H10F 39/811; H10D 30/62; H10D 80/251; H10F 30/225; H10F 39/103

(57) ABSTRACT

Provided is an image sensor having a chip-stacked structure, which may reduce the number of through-wires penetrating a transistor layer while avoiding connection by large metal pads between chips. The image sensor includes a first substrate including a first semiconductor layer and a first wiring layer, and the first semiconductor layer includes a photoelectric conversion element, and a second substrate including a second semiconductor layer and a second wiring layer, and the second semiconductor layer including a transistor. The first wiring layer is bonded to the second wiring layer, and a through-wire contacts a side surface of a gate or a side surface of a diffusion layer of the transistor, the through-wire penetrates the second substrate, and the through-wire is connected to the photoelectric conversion element through a wire of the first substrate.

### CROSS-REFERENCE TO RELATED APPLICATION

This application is based on and claims priority under 35 U.S.C. § 119 to Japanese Patent Application No. 2024-108036, filed on Jul. 4, 2024, in the Japan Patent Office, and to Korean Patent Application No. 10-2025-0029951, filed on Mar. 7, 2025, in the Korean Intellectual Property Office, the disclosures of which are incorporated by reference herein in their entirety.

### BACKGROUND

The inventive concepts relate to image sensors, and more particularly, to image sensors having a chip-stacked structure, and methods of manufacturing such image sensors.

Recently, technologies related to miniaturization and high image quality of complementary metal-oxide semiconductor (CMOS) image sensors (CIS) have been widely developed. Each pixel of a CIS has a photoelectric conversion element and a plurality of transistors. The plurality of transistors may include a transfer transistor, a reset transistor, a source follower transistor, and a select transistor. The source follower transistor is referred to as an amplification transistor. However, as pixels become more miniaturized, the area available for arranging transistors within a pixel is decreasing. In this regard, for example, conventional art discloses a stack structure in which transistors other than the transfer transistor within a pixel are placed in a different layer from a layer where the photoelectric conversion element exists. Furthermore, conventional art discloses a stack structure in which a plurality of transistors within a pixel are arranged in two layers different from a layer including the photoelectric conversion element.

### SUMMARY

The inventive concepts relate to image sensors having a chip-stacked structure, which may reduce the number of through-wires penetrating a substrate while avoiding connection by large metal pads between chips, and manufacturing methods thereof.

Furthermore, the technical objectives to be achieved by the disclosure are not limited to the above-described objective, and other technical objectives that are not mentioned herein would be clearly understood by a person skilled in the art from the description of the disclosure.

According to some aspects of the inventive concepts, there is provided an image sensor including a first substrate including a first semiconductor layer and a first wiring layer, the first semiconductor layer including a photoelectric conversion element, and a second substrate including a second semiconductor layer and a second wiring layer, the second semiconductor layer including a transistor, wherein the first wiring layer is bonded to the second wiring layer, and a through-wire contacts a side surface of a gate or a side surface of diffusion layer of the transistor, the through-wire penetrates the second substrate, and the through-wire is connected to the photoelectric conversion element through a wire of the first substrate.

Furthermore, according to other aspects of the inventive concepts, there is provided an image sensor including a first substrate including a first semiconductor layer and a first wiring layer, the first semiconductor layer including a photoelectric conversion element, a second substrate including a second semiconductor layer and a second wiring layer, the second semiconductor layer including a transistor, and a through-wire penetrating the second wiring layer, the through-wire extending toward the first wiring layer, wherein the first substrate is bonded to the second substrate in a structure in which the first wiring layer and the second wiring layer are between the first substrate and the second substrate, and the through-wire contacts a side surface of a gate or a side surface of a diffusion layer of the transistor, the through-wire is connected to a photoelectric conversion element through a wire of the first substrate.

Furthermore, according to other aspects of the inventive concepts, there is provided an image sensor including a first substrate including a first semiconductor layer and a first wiring layer, the first semiconductor layer including a photoelectric conversion element, a second substrate including a second semiconductor layer, a second wiring layer, and a third wiring layer, the second wiring layer and the third wiring layer being respectively arranged below and above the second semiconductor layer, the second semiconductor layer including a transistor, and a third substrate including a third semiconductor layer and a fourth wiring layer, the third semiconductor layer including a high functionality circuit, wherein the first substrate is bonded to the second substrate in a structure in which the first wiring layer and the second wiring layer are between the first substrate and the second substrate, the second substrate is bonded to the third substrate in a structure in which the third wiring layer and the fourth wiring layer are between the second substrate and the third substrate, and a through-wire contacts a side surface of a gate or a side surface of a diffusion layer of the transistor, the through-wire penetrates the second substrate, and the through-wire is connected to the photoelectric conversion element through a wire of the first substrate.

According to other aspects of the inventive concepts, there is provided a method of manufacturing an image sensor, the method including preparing a first substrate including a first semiconductor layer and a first wiring layer, preparing a second substrate including a second semiconductor layer and a second wiring layer, bonding the first substrate and the second substrate to each other in a structure in which the first wiring layer and the second wiring layer are arranged between the first substrate and the second substrate, thinning the second substrate, and forming a through-wire penetrating the second wiring layer and extending toward the first wiring layer.

In some example embodiments, the preparing of the first substrate may include forming a photoelectric conversion element layer including a photoelectric conversion element (PD), a floating diffusion (FD) area, and a transfer transistor (TG), on the first semiconductor layer, and forming the first wiring layer including an insulating layer, a gate wire, and an interlayer wiring layer, on the photoelectric conversion element layer.

In some example embodiments, the preparing of the second substrate may include forming a transistor layer including a reset transistor (RG), a source follower (SF) transistor, and a select (SEL) transistor, on the second semiconductor layer, and forming the second wiring layer including an insulating layer and a gate wire, on the transistor layer.

In some example embodiments, in the thinning of the second substrate, the second semiconductor layer may be removed up to a back side of the transistor layer.

In some example embodiments, in the thinning of the second substrate, the insulating layer may operate as a stopper.

In some example embodiments, the forming of the through-wire may include forming a protection layer on the back side of the transistor layer, forming a through-hole penetrating the second substrate and extending toward the first substrate, and filling the through-hole with a conductive material.

In some example embodiments, in the forming of the through-hole, the through-hole may be formed such that a side surface of a gate region of the SF transistor and a side surface of a source region of the RG transistor are in contact with the through-wire.

In some example embodiments, in the forming of the through-hole, a pattern alignment of an alignment mark of the through-wire may be performed on an alignment mark of a photomask layer of the first semiconductor layer.

In some example embodiments, the method may further include forming a third wiring layer including a rear wire on the second semiconductor layer.

In some example embodiments, the third wiring layer may include a capacitive element connected to the rear wire.

According to other aspects of the inventive concepts there is provided a method of manufacturing an image sensor, the method including preparing a first substrate including a first semiconductor layer and a first wiring layer, the first semiconductor layer including a photoelectric conversion element and a wire extending from the photoelectric conversion element into the first wiring layer; preparing a second substrate including a second semiconductor layer and a second wiring layer; bonding the first substrate to the second substrate in a structure in which the first wiring layer and the second wiring layer are between the first semiconductor layer and the second semiconductor layer; and forming a through-wire penetrating the structure through the second semiconductor layer, the second wiring layer, and extending into the first wiring layer to contact the wire.

According to other aspects of the inventive concepts there is provided a pixel of an image sensor, the pixel including a first substrate including a photoelectric conversion element and a wiring layer electrically connected to the photoelectric conversion element; and a second substrate bonded to the first substrate, the second substrate including a nano through-silicon via (nTSV) extending through the second substrate, the TSV contacting the wiring layer, the second substrate including transistor, a side surface of a gate or a side surface of a diffusion layer of the transistor contacts a side surface of the TSV.

### BRIEF DESCRIPTION OF THE DRAWINGS

Some example embodiments will be more clearly understood from the following detailed description taken in conjunction with the accompanying drawings in which:

FIG. 1 is a schematic diagram illustrating a configuration of an image sensor according to some example embodiments;

FIG. 2 is a schematic cross-sectional view of a configuration of one pixel in the image sensor of FIG. 1;

FIG. 3 is a schematic plan view showing a horizontal cross-sectional configuration of a second substrate taken along line I-I′ of FIG. 2;

FIG. 4 is a circuit diagram illustrating a circuit configuration of a pixel of FIG. 2;

FIG. 5 is a flowchart showing a process of manufacturing the image sensor of FIG. 1;

FIG. 6 is a schematic cross-sectional view illustrating a process of preparing a first substrate of FIG. 2;

FIG. 7 is a schematic cross-sectional view illustrating a process of preparing the second substrate of FIG. 2;

FIG. 8 is a schematic plan view illustrating a horizontal cross-sectional configuration of a second substrate taken along line III-III′ of FIG. 7;

FIG. 9 is a schematic diagram illustrating a process of aligning and bonding the first substrate of FIG. 6 to the second substrate of FIG. 7;

FIG. 10 is a schematic cross-sectional view illustrating a process of thinning the second substrate of FIG. 9;

FIG. 11 is a schematic cross-sectional view illustrating a process of forming a through-wire on the first substrate and the second substrate of FIG. 10;

FIG. 12 is a schematic cross-sectional view illustrating pattern alignment by alignment marks during through-wire formation;

FIG. 13 is a schematic cross-sectional view illustrating formation of an etching stopper during through-wire formation;

FIG. 14 is a schematic cross-sectional view illustrating a case where the through-wire is formed misaligned from a metal land during the formation of the etching stopper;

FIG. 15 is a schematic cross-sectional view illustrating a configuration of an image sensor according to some example embodiments;

FIG. 16 is a schematic cross-sectional view illustrating a configuration of an image sensor according to some example embodiments;

FIG. 17 is a schematic cross-sectional view illustrating a configuration of an image sensor according to some example embodiments;

FIG. 18 is a schematic cross-sectional view illustrating a configuration of an image sensor according to some example embodiments; and

FIG. 19 is a plan view illustrating a configuration of a second substrate of FIG. 18.

### DETAILED DESCRIPTION

Hereinafter, some example embodiments of the inventive concepts will be described in detail with reference to the attached drawings. Throughout the drawings, like reference numerals denote like elements. Sizes of components in the drawings may be exaggerated for convenience of explanation, and clarity. In this regard, the present example embodiments may have different forms and should not be construed as being limited to the descriptions set forth herein.

When a component is disposed “above” or “on” to another component, the component may be only directly on the other component or above the other components in a non-contact manner.

The expression of singularity includes the expression of plurality unless clearly specified otherwise in context. Furthermore, it will be further understood that the terms “comprises” and/or “comprising” used herein specify the presence of stated features or elements, but do not preclude the presence or addition of one or more other features or elements.

Furthermore, the use of the terms “a,” “an,” “the,” and similar referents in the context of describing the disclosure is to be construed to cover both the singular and the plural.

Also, the operations of all methods described herein can be performed in any suitable order unless otherwise indicated herein or otherwise clearly contradicted by context. The disclosure is not limited to the described order of the steps. The use of any and all examples, or language (e.g., “such as”) provided herein, is intended merely to better illuminate the disclosure and does not pose a limitation on the scope of the disclosure unless otherwise claimed.

For reference, in conventional methods, after a photoelectric conversion element layer including a photoelectric conversion element and a transfer transistor is formed on a first substrate, a transistor layer is formed on a second substrate disposed above the photoelectric conversion element layer. The transistor layer may include a reset transistor (RG), a select (SEL) transistor, and a source follower (SF) transistor. The transistor of the transistor layer is referred to as a pixel transistor, and constitutes a pixel circuit for driving a pixel. A wiring layer of the second substrate is formed only above the transistor layer to avoid a heat process during transistor formation. Accordingly, a wire to a transfer transistor or a floating diffusion area adjacent to the photoelectric conversion element needs to be wired from above the transistor layer to penetrate the transistor layer. A complementary metal-oxide semiconductor (CMOS) image sensor (CIS) of a fine pixel, which is under development, often has a configuration in which a plurality of photoelectric conversion elements are connected to one pixel circuit. In other words, in the CIS of a fine pixel, a plurality of transfer transistors are adjacent to one floating diffusion area. Accordingly, the number of connection wires, each connecting a plurality of photoelectric conversion elements of the first substrate and one pixel circuit of the second substrate, is plural. For the plurality of connection wires, a plurality of through-wires that penetrate each transistor layer are needed. Accordingly, due to the plurality of connection wires, an area available for arranging pixel transistors in the transistor layer is limited.

Furthermore, in conventional art, an imaging apparatus has a stack structure in which a sensor chip including a photoelectric conversion element in a photoelectric conversion element layer and two circuit chips including a pixel circuit in a transistor layer are included. In this structure, the respective chips each have a wiring layer on the surfaces facing each other. The respective chips are bonded to each other as metal pads of the wiring layer are aligned with each other. Accordingly, the photoelectric conversion element of the sensor chip and the transistor of the pixel circuit are connected to each other, and the transistors of the two circuit chips are connected to each other. In this case, as the connection of each wire does not need to use a through-wire, there is no area in the transistor layer where the transistor cannot be placed. However, as the sizes of metal pads between chips are large, there is a limit to the number of metal pads that can be connected. Furthermore, the capacitance around the metal pad is large. In particular, when a metal pad is used to connect a floating diffusion area, the large capacitance may cause a decrease in conversion efficiency or crosstalk.

Considering the above issues, the inventive concepts provide an image sensor which may reduce the number of through-wires penetrating a transistor layer while avoiding connection by large metal pads between chips.

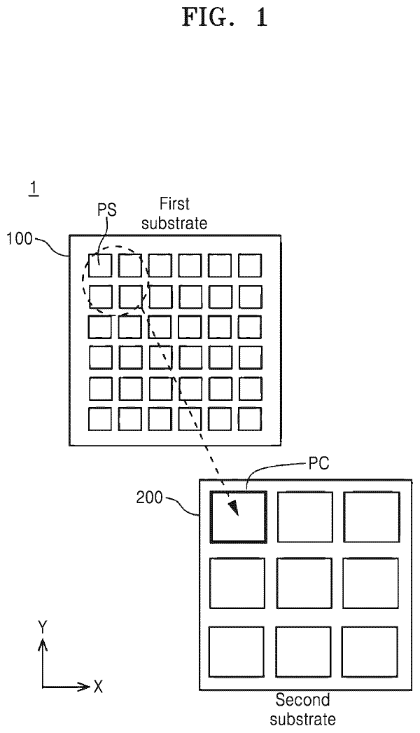

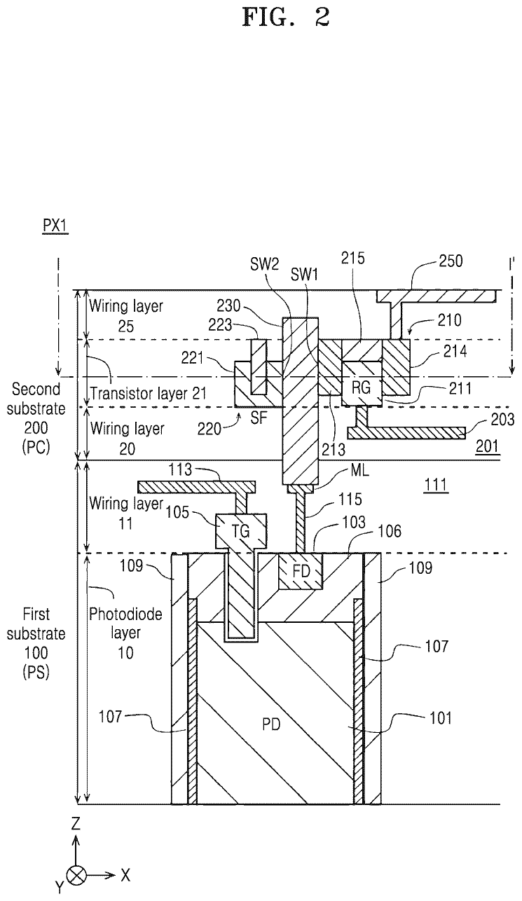

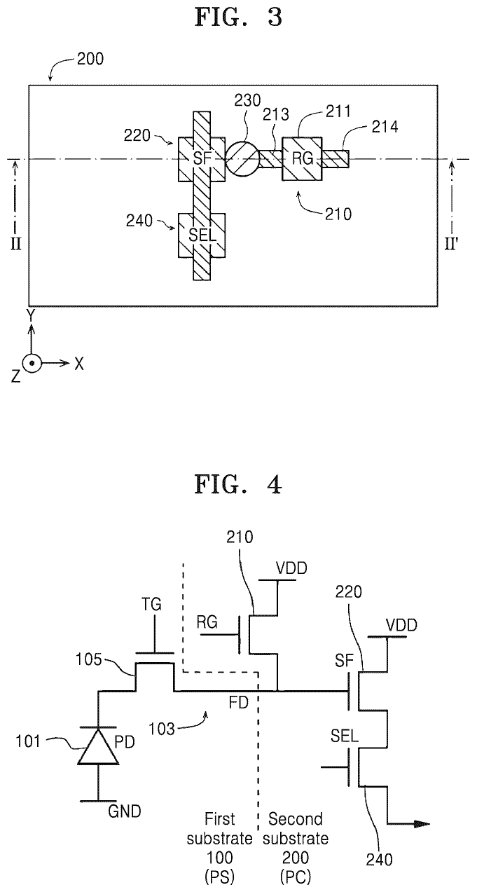

FIG. 1 is a schematic diagram illustrating a configuration of an image sensor 1 according to some example embodiments, and FIG. 2 is a schematic cross-sectional view illustrating a configuration of a pixel PX1 of the image sensor 1 of FIG. 1. Furthermore, FIG. 3 is a schematic plan view illustrating a horizontal cross-sectional configuration of a second substrate 200 of FIG. 2 taken along line I-I′. The cross-sectional view of FIG. 2 corresponds to a vertical cross-sectional configuration of a first substrate 100 (not shown) and the second substrate 200 of FIG. 3 taken along line II-II′. Furthermore, FIG. 4 is a circuit diagram illustrating a circuit configuration of a pixel of FIG. 2. In FIG. 4, a dashed line shows a boundary between the first substrate 100 and the second substrate 200.

Referring to FIGS. 1 to 4, the image sensor 1 may include, for example, as main elements, the first substrate 100 and the second substrate 200. A plurality of portions (hereinafter, referred to as the ‘sensing portions PS’), each having a function of outputting electric charges according to light incident on the image sensor 1, may be formed on the first substrate 100 in a horizontal direction (X direction) and a vertical direction (Y direction) at equal intervals. Furthermore, a plurality of portions (hereinafter, referred to as the ‘pixel circuits PC’), each outputting a voltage signal (hereinafter, referred to as the ‘pixel signal’) of an amplitude according to the amount of electric charges from the sensing portion PS, may be formed in the second substrate 200 in the horizontal direction and the vertical direction at equal intervals.

Furthermore, one pixel circuit PC may be commonly used by a plurality of sensing portions PS. In FIG. 1, for example, a case in which one pixel circuit PC is commonly used by four sensing portions PS is illustrated (a part indicated by a dashed circle and an arrow in FIG. 1). A case in which one pixel circuit PC corresponds to one sensing portion PS is illustrated in FIG. 2 and below. In the following descriptions, one sensing portion PS and one pixel circuit PC corresponding to the sensing portion PS are collectively referred to as a pixel PX.

In FIG. 1, for explanation, the image sensor 1 is illustrated as being divided in the first substrate 100 and the second substrate 200. However, actually, as illustrated in FIG. 2, the image sensor 1 may have a structure in which the second substrate 200 is stacked on the first substrate 100. As described below, in the image sensor 1, a wiring layer 11 of the first substrate 100 and a wiring layer 20 of the second substrate 200 are bonded to each other. In the following descriptions, a stack direction of the first substrate 100 and the second substrate 200 is a Z direction, a direction orthogonal to the Z direction is the X direction, and a direction orthogonal to the Z direction and the X direction is the Y direction.

One sensing portion PS formed on the first substrate 100 and one pixel circuit PC formed on the second substrate 200 may constitute one pixel PX. A plurality of sensing portions PS may be arranged on the first substrate 100 in the X direction and the Y direction, and a plurality of pixel circuits PC may be arranged on the second substrate 200 in the X direction and the Y direction. The sensing portions PS and the pixel circuits PC may constitute a plurality of pixels arranged on an X-Y plane in a matrix shape. In FIG. 2, an enlarged cross-section of one pixel PX is illustrated as an example.

The image sensor 1 may include a pixel value read part that is not shown. The pixel value read part may read out a pixel value of the pixel PX of a target to be read out by controlling a plurality of pixels arranged in a matrix form on the first substrate 100 and the second substrate 200. The pixel value read part may include a horizontal scan circuit, a correlated double sampling (CDS) circuit, an analog-to-digital converter (ADC), a vertical scan circuit, a control circuit, etc. The horizontal scan circuit may output a read-out signal to the pixel PX in a row of the target to be read out to control which row of the matrix of the pixel PX to read out. The CDS circuit may perform a CDS process on a pixel signal output from the pixel PX in a row selected by the horizontal scan circuit. The ADC is a circuit for converting an analog signal to a digital signal. The vertical scan circuit is a circuit for selecting an output signal line through which a pixel signal converted to a digital signal is output. The control circuit may control the horizontal scan circuit, the CDS circuit, the ADC, and the vertical scan circuit.

The first substrate 100 may include a photoelectric conversion element layer 10 that is a semiconductor layer and the wiring layer 11 stacked on the photoelectric conversion element layer 10. The photoelectric conversion element layer 10 may be formed by, for example, a silicon single crystal wafer, a silicon epitaxial layer, or a silicon on insulator (SOI) substrate. A p-type well area may be formed as the photoelectric conversion element layer 10 is doped with, for example, p-type impurities.

A photoelectric conversion element (PD) 101, a floating diffusion (FD) area 103, and a transfer transistor (TG) 105 may be formed in the photoelectric conversion element layer 10. Furthermore, p-type well areas 106 and 107 may be disposed on a side surface and above the PD 101.

The PD 101 may be a part that converts light incident on the image sensor 1 to electric charges. The image sensor 1 of some example embodiments, which is, for example, a back illuminated image sensor, may include, as described below, a color filter and a light-receiving lens, which are not shown, on the back side of the first substrate 100 (the opposite side to the second substrate 200).

The PD 101 may have an n-type area doped with n-type impurities having different conductivity from that of the p-type well area, and a pn junction may be formed by the n-type area and the p-type well area. In the pn junction, electron hole pairs may be generated according to the strength of incident light. Accordingly, electric charges (electrons) according to the strength of incident light may be output from the PD 101. As illustrated in FIG. 4, an anode electrode of the PD 101 may be connected to a ground GND of the sensing portion PS, and a cathode electrode of the PD 101 may be connected to the FD area 103 via the TG 105.

The FD area 103 may have capacitance and accumulate electric charges generated by the PD 101. The FD area 103 may be positioned in an upper layer portion of the photoelectric conversion element layer 10 and configured as an n-type semiconductor area having different conductivity from the p-type well area 106. One side end portion of an interlayer wire 115 of the wiring layer 11 may be connected to the FD arca 103.

The TG 105 may control transmission of the electric charges output from the PD 101 to the FD area 103 according to a gate voltage. In the image sensor 1 of some example embodiments, the TG 105 may be configured by, for example, a fin-fin field-effect transistor (FET). A drain region of the TG 105 may be connected to the FD area 103, and a source region of the TG 105 may be connected to the cathode electrode of the PD 101. Furthermore, one end portion of a gate wire 113 of the wiring layer 11 may be connected to a gate region of the TG 105. A read-out signal from the horizontal scan circuit may be supplied to the gate region of the TG 105. For example, when a high voltage is applied to the gate region of the TG 105, the TG 105 may be in an ON state and transmit the electric charges output from the PD 101 to the FD area 103. In contrast, when a low voltage is applied to the gate region of the TG 105, the TG 105 may be in an OFF state, and thus the electric charges to the FD area 103 may not be transmitted (see FIG. 4). The gate region of the TG 105 may be formed of, for example, metal or polysilicon.

A device isolation layer 109 may have a certain thickness in the X direction between two adjacent PDs 101, and may electrically separate (insulate) between the PDs 101 that are adjacent to each other and extend in the Y direction and the Z direction. The device isolation layer 109 may be formed of, for example, silicon oxide.

An insulating layer 111, the gate wire 113, and the interlayer wire 115 may be formed in the wiring layer 11. The gate wire 113 and the interlayer wire 115 may be formed of, for example, metal such as copper. The insulating layer 111 may be formed by stacking, for example, silicon oxide, on the photoelectric conversion element layer 10. One end portion of the gate wire 113 may be connected to the gate region of the TG 105, and the other end portion of the gate wire 113 may be connected to the horizontal scan circuit that is not shown. Furthermore, the interlayer wire 115 may be connected to a through-wire 230 that penetrates the first substrate 100 and the second substrate 200 in the FD area 103. A metal land ML may be formed on the interlayer wire 115, and as the metal land ML contacts the through-wire 230, the FD area 103 and the through-wire 230 may be electrically connected to each other. Accordingly, the through-wire 230 may be connected to the cathode area of the PD 101 through the interlayer wire 115, the FD area 103, and the TG 105.

As such, the interlayer wire 115 and the through-wire 230 may be connected to each other by being brought into contact in the wiring layer 11. Due to the contact between the metal land ML and the through-wire 230, a contact area may be reduced compared with a connection between metal pads. Accordingly, an increase in capacitance in a connection part may be restricted or reduced.

The color filter and the light-receiving lens, which are not shown, may be arranged on the back side of the first substrate 100 (the opposite side to the second substrate 200). The color filter may be arranged at a position facing the PD 101. The light-receiving lens may be arranged at a position facing the PD 101, for example, through the color filter.

The second substrate 200 may include the wiring layer 20, a transistor layer 21 that is a semiconductor layer formed on the wiring layer 20, and a second wiring layer 25 formed on the transistor layer 21.

The through-wire 230, an insulating layer 201, and a gate wire 203 may be formed in the wiring layer 20. The gate wire 203 may have one end portion connected to a gate region 211 of an RG transistor 210.

The RG transistor 210, an SF transistor 220, the through-wire 230, and an SEL transistor 240 may be formed in the transistor layer 21.

The RG transistor 210 may include the gate region 211, a source region 213, a drain region 214, and a channel region 215. The RG transistor 210 may perform the role of resetting the electric potential of the FD area 103 where electric charges are accumulated, depending on the electric potential of the gate region 211 (gate electric potential). The source region 213, the drain region 214, and the channel region 215 may constitute a diffusion layer. The gate region 211 may be connected to one end portion of the gate wire 203 of the wiring layer 20. Furthermore, the source region 213 may be connected to the through-wire 230. A side wall (side surface) SW1 of the source region 213 may be in contact with a side surface of the through-wire 230. The drain region 214 may be connected to power VDD through a rear wire (metal wire) 250.

The SF transistor 220 may include a gate region 221, a source region, a drain region, and a channel region 223. The SF transistor 220 may amplify an electric potential change of the FD area 103 and output the amplified electric potential change as an analog signal. A side wall (side surface) SW2 of the gate region 221 of the SF transistor 220 may be in contact with the side surface of the through-wire 230. The gate region 221 of the SF transistor 220 may be connected to the FD area 103 through the through-wire 230 and the interlayer wire 115, and the drain region of the SF transistor 220 may be connected to the power VDD. Furthermore, the source region of the SF transistor 220 may be connected to the drain region of the SEL transistor 240. The SF transistor 220 may output electric potential corresponding to the electric charges accumulated in the FD area 103 to the SEL transistor 240. In other words, the SF transistor 220 may convert (amplify) the electric charges accumulated in the FD area 103 to a voltage according to the amount of electric charges.

As such, in the image sensor 1 of some example embodiments, the through-wire 230 may be in contact with side surfaces of the diffusion layer of the RG transistor 210 and the gate region 221 of the SF transistor 220. The through-wire 230 may be, for example, a nano-through silicon via (nTSV) that penetrates the first substrate 100 and the second substrate 200. The nTSV may be formed of, for example, copper, tungsten, etc.

The SEL transistor 240 may control an output in an output signal line of the analog signal supplied from the SF transistor 220. The SEL transistor 240 may include a gate region, a source region, a drain region, and a channel region. The drain region of the SEL transistor 240 may be connected to the source region of the SF transistor 220, and the source region of the SEL transistor 240 may be connected to the output signal line. Furthermore, a column select signal may be supplied from the vertical scan circuit to gate region of the SEL transistor 240. When a column select control signal is low, the SEL transistor 240 may be in an OFF state, and the SF transistor 220 may be electrically separated from the output signal line. Accordingly, when the control signal is low, the pixel signal may not be output from the pixel PX. In contrast, when the control signal is high, the SEL transistor 240 is in an ON state, and the SF transistor 220 may be electrically connected to the output signal line. Accordingly, the analog signal output from the SF transistor 220 may be input to the output signal line as the pixel signal of the pixel PX.

The rear wire 250 may be formed in the second wiring layer 25. One end portion of the rear wire 250 may be connected to the drain region 214 of the RG transistor 210. In other words, the second substrate 200 may include the rear wire 250 that is connected to the RG transistor 210 from the opposite surface to the first substrate 100. Accordingly, the rear wire 250 may be connected to the through-wire 230 via the RG transistor 210.

As such, the image sensor 1 may include the first substrate 100, the first substrate 100 may include the photoelectric conversion element layer 10 and the wiring layer 11, and the photoelectric conversion clement layer 10 may include the PD 101. Furthermore, the image sensor 1 may include the second substrate 200, the second substrate 200 may include the wiring layer 20 and the transistor layer 21, and the transistor layer 21 may include at least one transistor. In the image sensor 1 of some example embodiments, the first substrate 100 and the second substrate 200 may have a structure in which the wiring layers 11 and 20 of the first substrate 100 and the second substrate 200 are bonded to each other.

Furthermore, the FD area 103 of the photoelectric conversion element layer 10 may be connected to the RG transistor 210 and the SF transistor 220 arranged in the transistor layer 21, through the through-wire 230. The through-wire 230 may be in contact with the RG transistor 210 of the transistor layer 21 at the side wall of the diffusion layer of the RG transistor 210. The through-wire 230 may be electrically connected to the FD area 103 of the photoelectric conversion element layer 10 by the contact between the interlayer wire 115 of the wiring layer 11 and the through-wire 230. As the through-wire 230 is connected to an end portion (surface) of the interlayer wire 115 formed toward the surface of the first substrate 100, the length of a through-hole may be shortened during the formation of the through-wire 230, and thus it may be possible to form the hole diameter smaller, thereby obtaining an effect of reducing the pixel size.

In the image sensor 1 of some example embodiments, a Fin-FET may be employed in the RG transistor 210, the SF transistor 220, and the SEL transistor 240 of the transistor layer 21. In the pixel circuit, although it is possible to use a Fin-FET used for general logic circuits, a relatively large Fin-FET designed for the pixel circuit may be used. By using the Fin-FET, after thinning the transistor layer 21, a contact from the back side of the second substrate 200 (the transistor layer 21) to a gate of the Fin-FET or the diffusion layer may be easily made, and adding a wiring layer to the back side of the transistor layer 21 may be possible. Accordingly, the total number of wires in the wiring layer 11 between the photoelectric conversion element layer 10 and the transistor layer 21 may be reduced.

Furthermore, by using the Fin-FET, as wires may be formed on the back side of the transistor layer 21, the number of wires or wiring layers within the second substrate 200 may be reduced accordingly, and thus the second substrate 200 may be thinned. Accordingly, as described above, during the formation of the through-wire 230, the length of a through-hole may be shortened, and the diameter of the through-wire 230, for example, the nTSV, may be reduced. Accordingly, the interval between the through-wires 230 may be reduced.

Additionally, by using the Fin-FET, the connection between the through-wire 230 and the Fin-FET may be easily made by using the vertically long side surface of the gate region 221 of the SF transistor 220 and a vertically long side surface of the source region 213 of the RG transistor 210 in the transistor layer 21. Accordingly, the connection between the photoelectric conversion element layer 10 and the transistor layer 21 may be easily made.

The horizontal scan circuit may control transmission of the TG 105 at each pixel PX by outputting a read-out signal to the pixel PX in a row of the target to be read out. When the TG 105 is in an ON state, the electric charges of the PD 101 may be transmitted to the FD arca 103. Furthermore, the horizontal scan circuit may control a reset operation of the RG transistor 210 at each pixel PX by outputting a reset signal to the pixel PX in the row of the target to be read out. When the RG transistor 210 is in an ON state, the electric potential of the FD arca 103 may be reset to the electric potential of the power VDD. The SF transistor 220 may generate, as a pixel signal, a signal of a voltage according to the amount of electric charges retained in the FD area 103. In detail, the SF transistor 220 may constitute a source follower type amplifier, and may output a pixel signal of the voltage according to the amount of electric charges generated in the PD 101. The SEL transistor 240 may control the output timing of a pixel signal from the pixel value read part. When the SEL transistor 240 is in an ON state, the SEL transistor 240 may output a pixel signal converted by the SF transistor 220 to the CDS circuit through the output signal line.

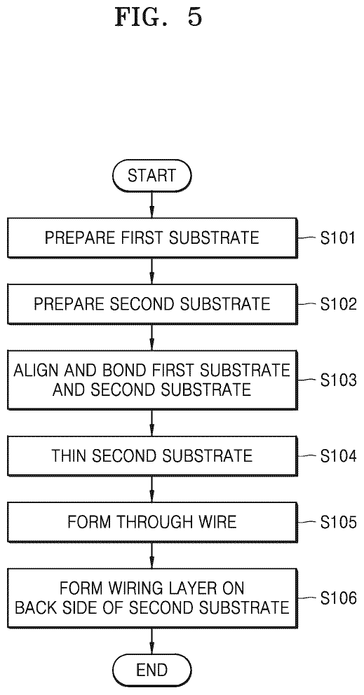

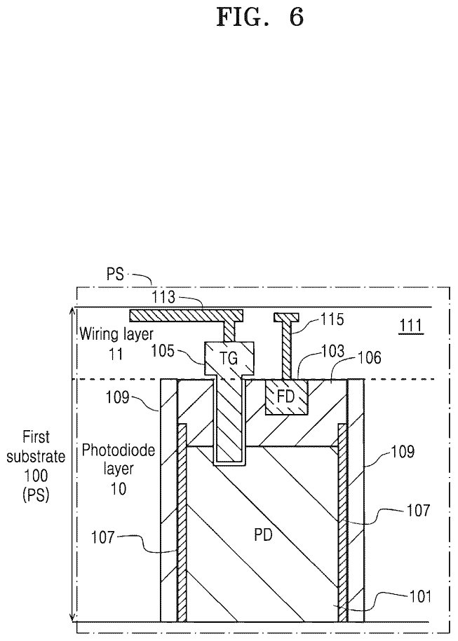

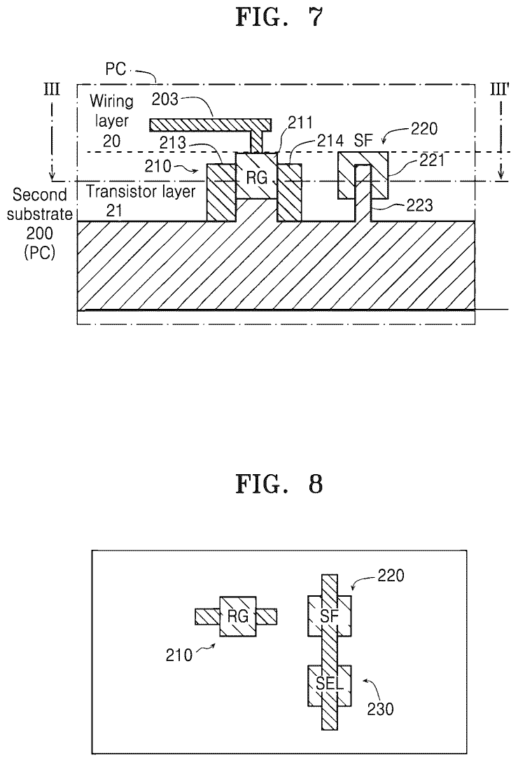

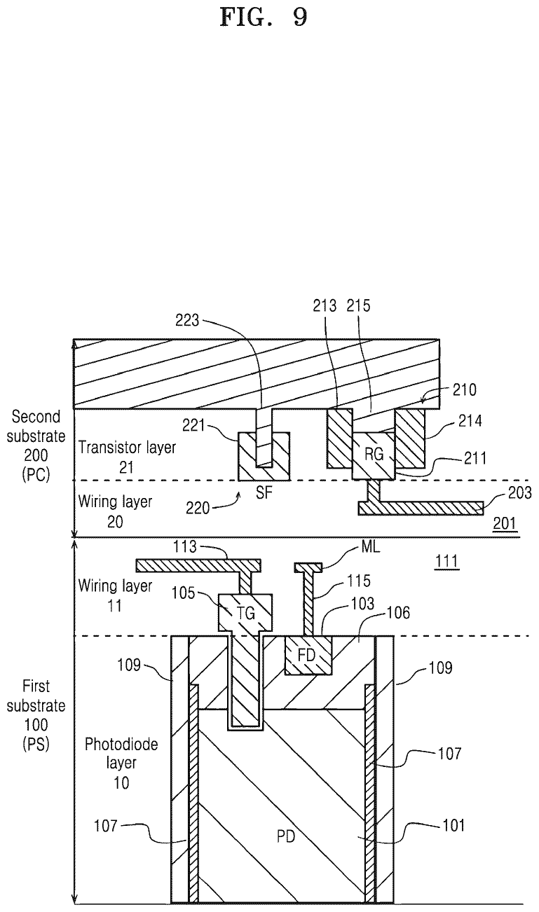

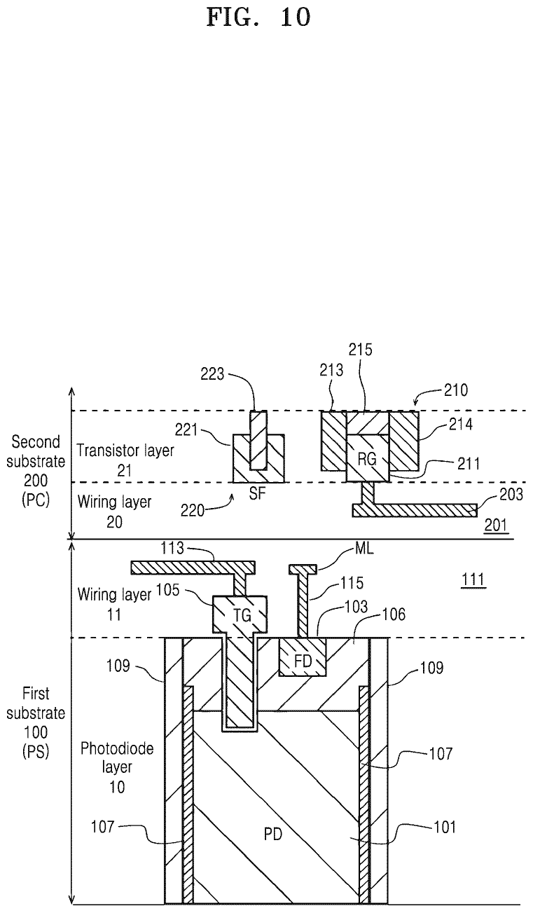

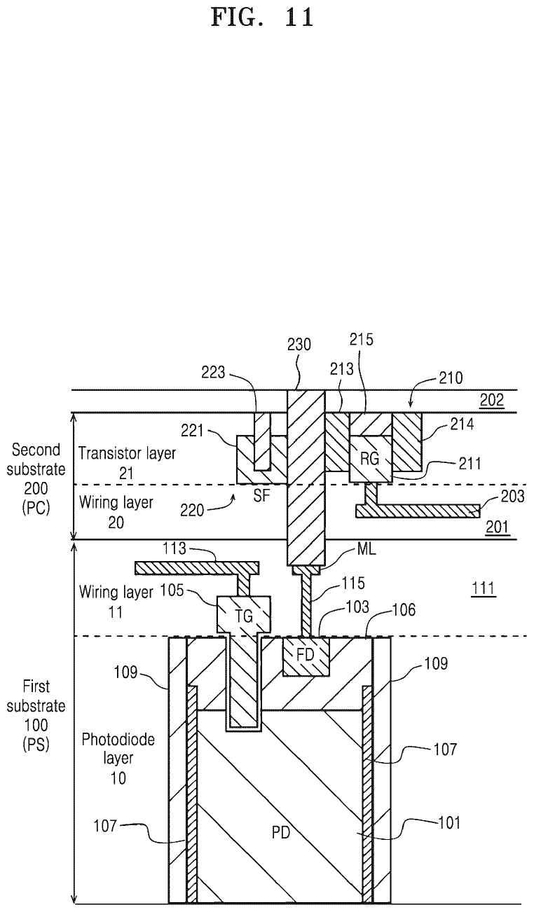

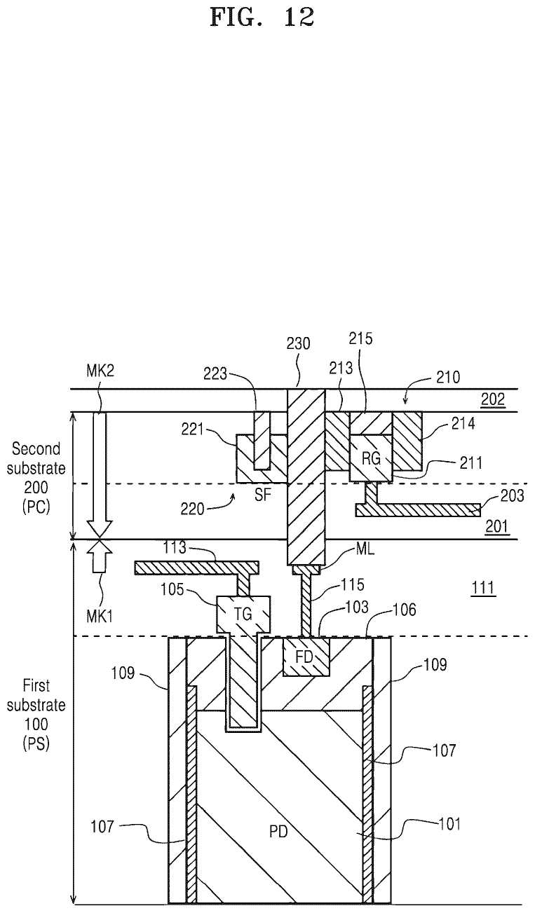

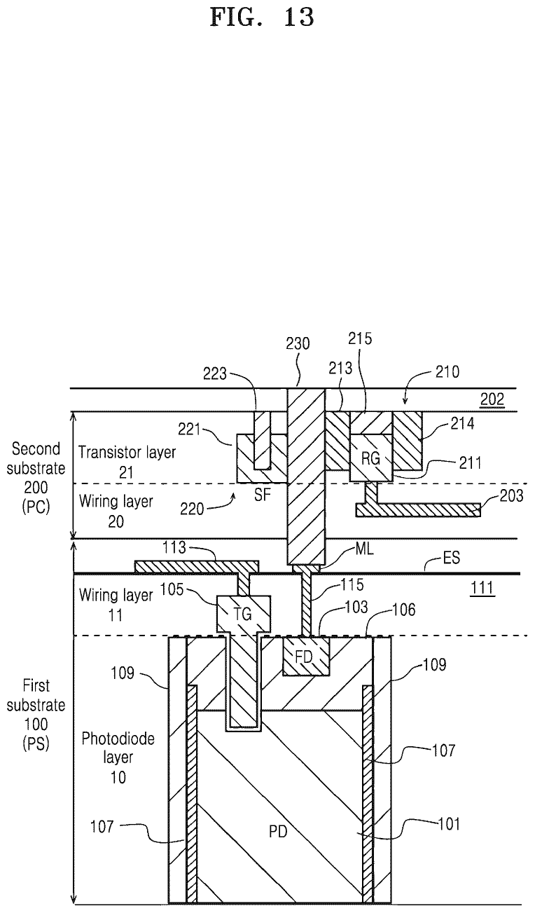

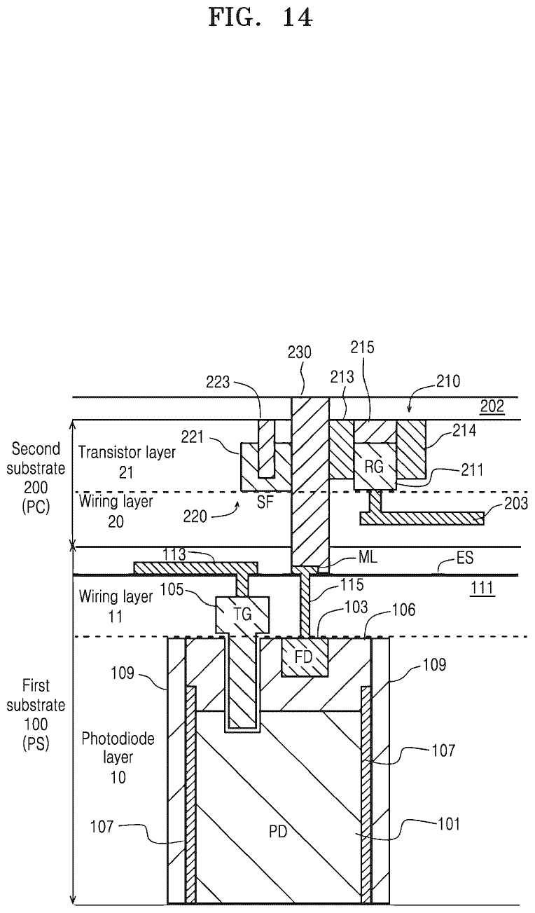

FIG. 5 is a flowchart showing a process of manufacturing an image sensor according to some example embodiments. FIG. 6 is a schematic cross-sectional view illustrating a process of preparing the first substrate 100 of FIG. 2. FIG. 7 is a schematic cross-sectional view illustrating a process of preparing the second substrate 200 of FIG. 2. Furthermore, FIG. 8 is a schematic plan view illustrating a horizontal cross-sectional configuration of the second substrate 200 taken along line III-III′ of FIG. 7. FIG. 9 is a schematic diagram illustrating a process of aligning and bonding the first substrate 100 of FIG. 6 to the second substrate 200 of FIG. 7. Furthermore, FIG. 10 is a schematic cross-sectional view illustrating a process of thinning the second substrate 200 of FIG. 9. FIG. 11 is a schematic cross-sectional view illustrating a process of forming a through-wire on the first substrate 100 and the second substrate 200 of FIG. 10. FIG. 12 is a schematic cross-sectional view illustrating pattern alignment by alignment marks during through-wire formation. FIG. 13 is a schematic cross-sectional view illustrating formation of an etching stopper during through-wire formation. FIG. 14 is a schematic cross-sectional view illustrating a case where the through-wire is formed misaligned from a metal land during the formation of the etching stopper. While the process of manufacturing the image sensor is described above with reference to FIGS. 1 to 4 together, already explained portions in the description section with reference to FIGS. 1 to 4 are briefly explained or omitted.

Referring to FIGS. 5 to 14, in a method of manufacturing an image sensor, according to some example embodiments, as illustrated in FIG. 5, first, the first substrate 100 is prepared (S101). As illustrated in FIG. 6, the photoelectric conversion element layer 10 including the PD 101, the FD area 103, the TG 105, the p-type well areas 106 and 107, and the device isolation layer 109 is formed on a silicon (Si) substrate. Next, the wiring layer 11 including the insulating layer 111, the gate wire 113, and the interlayer wire 115 is formed on the photoelectric conversion element layer 10. Accordingly, the sensing portion PS may be formed in the first substrate 100.

Next, the second substrate 200 is prepared (S102). As illustrated in FIGS. 7 and 8, the transistor layer 21 including the RG transistor 210, the SF transistor 220, and the SEL transistor 240 is formed on the Si substrate. Accordingly, the pixel circuit PC may be formed on the second substrate 200. Next, the wiring layer 20 including the insulating layer 201 and the gate wire 203 is formed on the transistor layer 21.

Next, the first substrate 100 and the second substrate 200 are aligned with and bonded to each other (S103). As illustrated in FIG. 9, after rotating the second substrate 200 by 180° to reverse the front and the back, the second substrate 200 is aligned with the first substrate 100 to match the position of the second substrate 200 and the position of the first substrate 100 by using a well-known alignment method, and the second substrate 200 is bonded to the first substrate 100. In the method of manufacturing an image sensor, according to some example embodiments, the alignment and bonding may be alignment and bonding between the insulating layer 111 and the insulating layer 201, not alignment and bonding between metal wires.

Next, the second substrate 200 is thinned (S104). As illustrated in FIG. 10, the second substrate 200 may be thinned up to the back side (the upper surface of FIG. 10) of the transistor layer 21. In the method of manufacturing an image sensor, according to some example embodiments, as the Fin-FET is used as a transistor of the transistor layer 21, an area of the insulating layer 201 on the back side of the transistor layer 21 is large compared with the planar type so that the insulating layer 201 may act as a stopper in the thinning process.

Next, the through-wire 230 is formed (S105). As illustrated in FIG. 11, an insulating layer 202 for protecting the back side of the transistor layer 21 is formed on the back side of the second substrate 200 (an upper surface of FIG. 11), and then a through-hole is formed at a position corresponding to the metal land ML of the interlayer wire 115 in the first substrate 100 and the second substrate 200. In this state, the through-hole may be formed to contact the side surface of the gate region 221 of the SF transistor 220 and the side surface of the source region 213 of the RG transistor 210. The through-wire 230 may be formed by filling a conductive material (e.g., copper, tungsten, etc.) in the through-hole that has been formed. In the method of manufacturing an image sensor, according to some example embodiments, as the Si substrate is thinned up to the back side of the transistor layer 21, there is an effect of facilitating formation of a through-hole. Furthermore, by forming the through-hole to contact the side surface of the gate region 221 of the SF transistor 220 and the side surface of the source region 213 of the RG transistor 210, as there is no need to form a dedicated wire to connect the gate region 221 of the SF transistor 220 and the source region 213 of the RG transistor 210, pixel size reduction may be further realized.

As illustrated in FIG. 12, when forming the through-wire 230, position misalignment may be reduced by performing a pattern alignment of an alignment mark MK2 of the through-wire 230 with an alignment mark MK1 of the uppermost layer of the photoelectric conversion element layer 10. As a result, the size of a pattern of the metal land ML of the interlayer wire 115 that receives the through-wire 230 may be reduced. Accordingly, the capacitance according to the contact between the through-wire 230 and the metal land ML may be reduced.

Furthermore, as illustrated in FIG. 13, when forming the through-wire 230, an etching stopper film (stopper area) ES may be formed in the wiring layer 11 of the first substrate 100. Accordingly, as illustrated in FIG. 14, during the formation of the through-wire 230, even when the nTSV is deviated from the metal land ML of the interlayer wire 115, the erosion of the insulating layer 111 in the first substrate 100 may be suppressed by the etching stopper film ES. Accordingly, a margin for the dimensions of the pattern of the metal land ML may be reduced.

Next, a wiring layer is formed on the back side of the second substrate 200 (S106). In detail, the second wiring layer 25 including the rear wire 250 is formed on the back side of the second substrate 200. One end portion of the rear wire 250 may be connected to the drain region 214 of the RG transistor 210. In some example embodiments, the formation of the second wiring layer 25 may be omitted.

In the image sensor 1 of some example embodiments described above, the first substrate 100 having the wiring layer 11 and the photoelectric conversion element layer 10, and the second substrate 200 having the wiring layer 20 and the transistor layer 21 may be bonded to the wiring layers 11 and 20 positioned therebetween. Furthermore, the image sensor 1 may include the through-wire 230 that penetrates the second substrate 200 and may be connected to the PD 101 through the interlayer wire 115 of the first substrate 100. The through-wire 230 may be in contact with the side surfaces SW1 and SW2 of the diffusion layer of the RG transistor 210 and the gate region 221 of the SF transistor 220 of the transistor layer 21. In other words, the through-wire 230 that penetrates the second substrate 200 and is formed at a position that contacts the side surface of the gate or the diffusion layer of the transistor of the transistor layer 21, may be connected to the PD 101 through the interlayer wire 115 of the first substrate 100. In the above description, a case in which the side surfaces of the gate region 221 of the SF transistor 220 and the diffusion layer of the RG transistor 210 contact the through-wire 230 is presented as an example. However, the inventive concepts are not limited to the above case, and the pixel circuit PC may be configured such that any one of the side surfaces of the gate region 221 of the SF transistor 220 and the diffusion layer of the RG transistor 210 is in contact with the through-wire 230.

According to the image sensor 1 of some example embodiments configured as above, the connection between metal pads having large dimensions between the first substrate 100 and the second substrate 200 may be avoidable, and in addition, the number of through-wires 230 that penetrate the transistor layer 21 may be reduced.

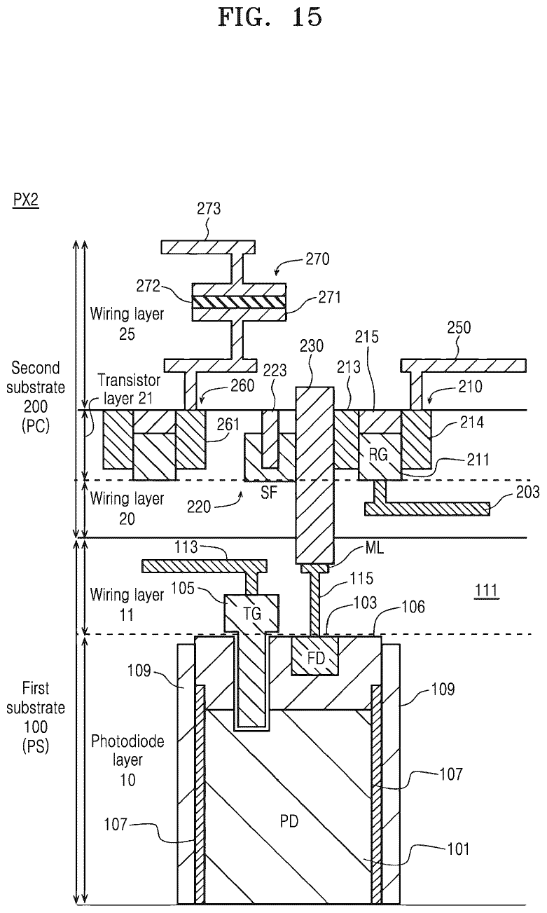

FIG. 15 is a schematic cross-sectional view illustrating a configuration of an image sensor according to some example embodiments, which corresponds to the cross-sectional view of FIG. 2. To avoid redundant descriptions, detailed descriptions on the same configuration as the image sensor 1 of the example embodiments of FIGS. 1 to 14 are omitted.

Referring to FIG. 15, the image sensor 1 of some example embodiments may differ from the image sensor 1 of FIG. 2 in that a pixel PX2 of the image sensor 1 of some example embodiments further includes a capacitive element 270 arranged on the back side of the second wiring layer 25 of the second substrate 200. In detail, as illustrated in FIG. 15, in the image sensor 1 of some example embodiments, a connection transistor 260 may be disposed on the transistor layer 21 of the second substrate 200, and the capacitive element 270 may be disposed on the back side of the second wiring layer 25 of the second substrate 200.

The connection transistor 260 may serve as a switching element for the capacitive element 270. The capacitive element 270 may be used as, for example, a lateral overflow integration capacitor (LOFIC), and may accumulate electric charges overflowing from the PD 101 or the FD area 103 through the connection transistor 260. Furthermore, the capacitive element 270 may also be used as a capacitance to accumulate signal charges of a pixel unit of a global shutter.

The capacitive element 270 may be metal-insulator-metal (MIM) having a stack structure of a metal electrode 271, an insulating layer 272, and a metal electrode 273. Alternatively, the capacitive element 270 may be a capacitor such as a MOS capacitor. A source region/drain region 261 of the connection transistor 260 may be connected to the metal electrode 271 on one side of the capacitive element 270.

In the image sensor 1 of some example embodiments, the capacitive element 270 may be arranged on the second wiring layer 25 of the back side of the transistor layer 21. Accordingly, there is no need to arrange a capacitive element in the wiring layers 11 and 20 between the photoelectric conversion element layer 10 and the transistor layer 21. Accordingly, the wiring layers 11 and 20 may be suppressed from being thickened. As a result, as a distance between a component such as the FD area 103 in the photoelectric conversion element layer 10 and a component such as a transistor in the transistor layer 21 decreases, a parasitic capacitance may be reduced. In other words, it may be effective in terms of improving conversion efficiency or suppressing crosstalk in the FD area 103.

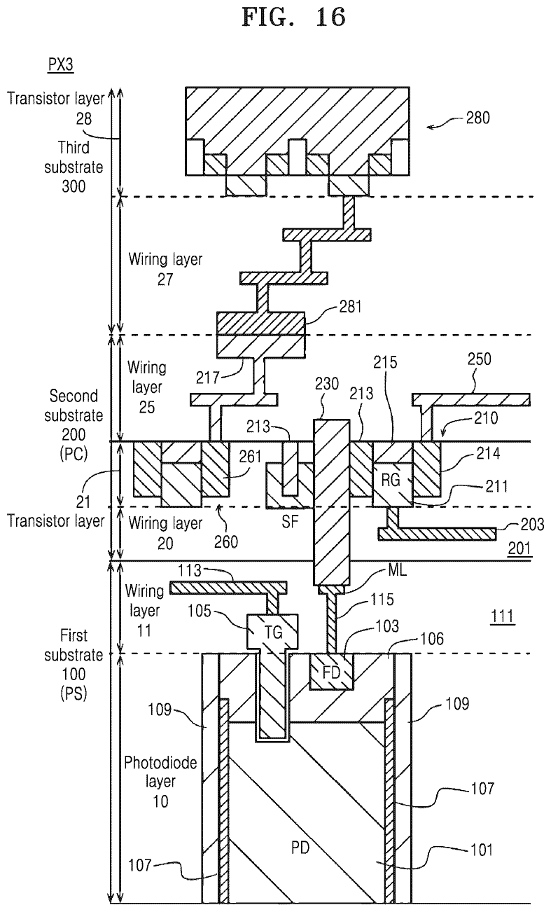

FIG. 16 is a schematic cross-sectional view illustrating a configuration of an image sensor according to some example embodiments, which corresponds to the cross-sectional view of FIG. 2. To avoid redundant descriptions, detailed descriptions are omitted for the same configuration as the configuration of the image sensor I according to the example embodiments of FIGS. 1 to 14.

Referring to FIG. 16, a pixel PX3 of the image sensor 1 of some example embodiments may differ from the image sensor 1 of FIG. 2 in that an additional circuit (hereinafter, referred to as the ‘high functionality circuit’) for high functionality of a pixel is formed on a third substrate 300. In detail, in the image sensor 1 of some example embodiments, the third substrate 300 may include a wiring layer 27 and a transistor layer 28 that is a semiconductor layer formed on the wiring layer 27. A wire (metal wire) 281 for connecting to a wire 217 of the second wiring layer 25 of the second substrate 200 may be formed on the wiring layer 27. Furthermore, a high functionality circuit 280 may be formed in the transistor layer 28.

The connection transistor 260 may be formed in the transistor layer 21 of the second substrate 200. The connection transistor 260 may serve as a switching element for the high functionality circuit 280 in the third substrate 300. When the connection transistor 260 is on, the high functionality circuit 280 may be connected to a circuit element of the second substrate 200 through the connection transistor 260. Furthermore, the wire 217 for connecting to the wire 281 of the wiring layer 27 of the third substrate 300 may be formed in the second wiring layer 25, and as a pad portion of the wire 217 contacts a pad portion of the wire 281, the wire 217 may be electrically connected to the wire 281. The wire 217 may be connected to the source region/drain region 261 of the connection transistor 260.

In general, when an additional high functionality circuit is provided in a pixel circuit to increase the function of a pixel of an image sensor, it may lead to an increase in the circuit size of the pixel circuit. In the image sensor 1 of some example embodiments, when aligning and bonding the second substrate 200 to the third substrate 300, the wire 217 and the wire 281 having pad portions are brought into contact with each other by the pad portions, thereby connecting the pixel circuit of the second substrate 200 to the high functionality circuit of the third substrate 300. Accordingly, function integration may be realized in fine pitch pixels.

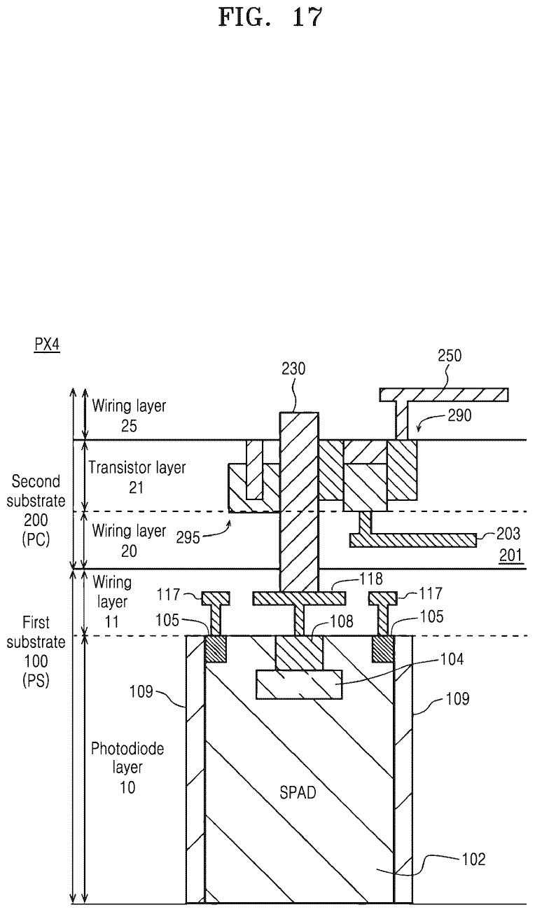

FIG. 17 is a schematic cross-sectional view illustrating a configuration of an image sensor according to some example embodiments, which corresponds to the cross-sectional view of FIG. 2. To avoid redundant descriptions, detailed descriptions are omitted for the same configuration as the configuration of the image sensor 1 according to some example embodiments of FIGS. 1 to 14.

Referring to FIG. 17, in the image sensor 1 of some example embodiments, a pixel PX4 may differ from the image sensor 1 of FIG. 2 in that a single-photon-avalanche-diode (SPAD) that is an avalanche photoelectric conversion element is used as a photoelectric conversion element of the sensing portion PS. In detail, in the image sensor 1 of some example embodiments, the first substrate 100 may include the photoelectric conversion element layer 10 and the wiring layer 11 stacked on the photoelectric conversion element layer 10. A SPAD 102, an anode electrode 105, a cathode electrode 108, and the device isolation layer 109 may be formed on the photoelectric conversion element layer 10, and an avalanche area 104 may be formed below the cathode electrode 108. An anode wire 117 and a cathode wire 118 may be formed in the wiring layer 11, and the cathode wire 118 may be electrically connected to the through-wire 230. The cathode wire 118 may be formed of, for example, metal such as copper.

In the configuration of the second substrate 200, a recharge transistor 290 and an input transistor 295 of a detection circuit (not shown) for detecting the output of a cathode may be formed in the transistor layer 21. In the image sensor 1 of some example embodiments, Fin-FETs may be used as the recharge transistor 290 and the input transistor 295, and by forming the through-wire 230 in a form of contacting the side wall thereof, it is possible to achieve miniaturization of the pixel size. Furthermore, by connecting the cathode wire 118 having the metal land ML to the through-wire 230, the depth and the diameter of the through-hole may be made shallow and small, respectively, it is possible to further reduce the pixel size.

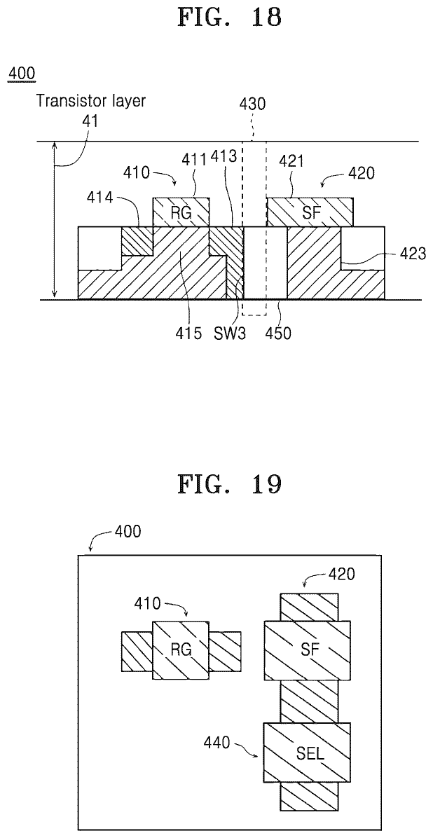

FIG. 18 is a schematic cross-sectional view illustrating a configuration of an image sensor according to some example embodiments, and FIG. 19 is a plan view illustrating a configuration of a second substrate of FIG. 18. To avoid redundant descriptions, detailed descriptions are omitted for the same configuration as the configuration of the image sensor 1 according to some example embodiments depicted in FIGS. 1 to 14.

Referring to FIGS. 18 and 19, the image sensor 1 of some example embodiments may differ from the image sensor 1 of FIG. 2 in that a planar-type transistor is used as the transistor of the pixel circuit PC. In the image sensor 1 of some example embodiments, as the configuration of the first substrate is the same as the first substrate 100 of the image sensor 1 of FIG. 2, detailed descriptions are omitted.

In the image sensor 1 of some example embodiments, a second substrate 400 may include a transistor layer 41. An RG transistor 410, an SF transistor 420, a through-via 430, and a SEL transistor 440 may be formed on the transistor layer 41. In the image sensor 1 of some example embodiments, the RG transistor 410, the SF transistor 420, and the SEL transistor 440 may each be a planar-type transistor. Furthermore, an element isolation layer 450 for electrically insulating transistors from each other may be arranged around each transistor in the transistor layer 41. In particular, the element isolation layer 450 may be formed thick around a position where the through-via 430 is formed. In other words, the element isolation layer 450 may be formed deeper than other positions from the substrate surface (a gate side) around the position where the through-via 430 is formed so that the bottom of the element isolation layer 450 reaches the back side of the substrate when the second substrate is thinned.

The RG transistor 410 may include a gate region 411, a source region 413, a drain region 414, and a channel region 415. The source region 413, the drain region 414, and the channel region 415 may constitute a diffusion layer. The channel region 415 may be connected to the through-via 430 through the source region 413. A side wall SW3 of the source region 413 may be in contact with a side surface of the through-via 430. The source region 413 having the side wall SW3 may include an impurity-doped layer deeper than the drain region 414. As the through-via 430 is in contact with the diffusion layer of source region 413 in the side wall SW3, contact resistance may be reduced, and the contact with the channel region 415 may be avoided. As the role of the RG transistor 410 is the same as the role of the RG transistor 210 in the example embodiments described above, a description thereof is omitted.

The SF transistor 420 may include a gate region 421 and a channel region 423. The gate region 421 of the SF transistor 420 may be electrically connected to the through-via 430 by contacting the same. Furthermore, a source region of the SF transistor 420 may be connected to a drain region of the SEL transistor 440.

As the functions of the SF transistor 420 and the SEL transistor 440 are the same as those of the SF transistor 220 and the SEL transistor 240 of the image sensor 1 of FIG. 2, descriptions thereof are omitted.

As such, in the image sensor 1 of some example embodiments, the transistor of the pixel circuit PC may be a planar-type transistor. The transistor layer 41 may have a partially different structure from general transistors in the structure of the element isolation layer 450 or the structure of the diffusion layer.

The configuration of the image sensor 1 described above is a configuration described in explaining the features of the above-described example embodiments, and the inventive concepts are not limited to the above-described configuration, and may be changed in various ways within the scope of the claims. Furthermore, the inventive concepts do not exclude the configuration of a general image sensor.

For example, in the image sensor 1 of FIG. 2, a case in which the RG transistor 210, the SF transistor 220, and the SEL transistor 240 of the pixel circuit PC are configured by Fin-FETs is described. However, for example, the RG transistor 210, the SF transistor 220, and the SEL transistor 240 of the pixel circuit PC may be configured by CMOS transistors.

Furthermore, in the flowchart described above, steps other than those shown in the flowchart may be included, or some steps may not be included. Furthermore, the order of steps may not be limited to the example embodiments described above. In addition, each step may be executed as one step in combination with other steps, may be executed as part of other steps, or may be executed by being divided into a plurality of steps.

While the inventive concepts have been particularly shown and described with reference to example embodiments thereof, it will be understood that various changes in form and details may be made therein without departing from the spirit and scope of the following claims.

What is claimed is:

1. An image sensor comprising:
a first substrate including a first semiconductor layer and a first wiring layer, the first semiconductor layer including a photoelectric conversion element; and
a second substrate including a second semiconductor layer and a second wiring layer, the second semiconductor layer including a transistor,
wherein the first wiring layer is bonded to the second wiring layer, and
a through-wire contacts a side surface of a gate or a side surface of a diffusion layer of the transistor, the through-wire penetrates the second substrate, and the through-wire is connected to the photoelectric conversion element through a wire of the first substrate.

2. The image sensor of claim 1, wherein the wire of the first substrate contacts the through-wire in the first wiring layer.

3. The image sensor of claim 1, wherein
the second semiconductor layer includes a first transistor and a second transistor, and
the through-wire contacts a side surface of a diffusion layer of the first transistor and a side surface of a gate of the second transistor.

4. The image sensor of claim 1, wherein the transistor of the second semiconductor layer includes a Fin-field effect transistor (FET).

5. The image sensor of claim 1, wherein the transistor of the second semiconductor layer includes a reset transistor (RG) or a source follower (SF) transistor.

6. The image sensor of claim 1, wherein the wire of the first substrate is connected to the photoelectric conversion element through a floating diffusion area.

7. The image sensor of claim 1, wherein the first wiring layer includes a stopper area that acts as a stopper in response to the through-wire being formed.

8. The image sensor of claim 1, wherein the second substrate includes a metal wire that is connected to the transistor of the second semiconductor layer, the metal wire extends from a first surface of the second substrate that is opposite a second surface of the second substrate, the second surface faces the first substrate.

9. The image sensor of claim 1, wherein the second substrate comprises a metal wire that is connected to the through-wire, the metal wire extends from a first surface of the second substrate that is opposite a second surface of the second substrate, the second surface faces the first substrate.

10. The image sensor of claim 1, wherein
the second substrate further includes a third wiring layer on the second wiring layer, and
a capacitive element on the third wiring layer.

11. The image sensor of claim 1, wherein the second substrate is connected to a third substrate through a metal wire extending from a first surface of the second substrate opposite a second surface of the second substrate, the second surface faces the first substrate.

12. The image sensor of claim 1, wherein the photoelectric conversion element of the first semiconductor layer includes an avalanche photoelectric conversion element.

13. The image sensor of claim 1, wherein the wire of the first substrate is connected to a cathode electrode of the photoelectric conversion element.

14. An image sensor comprising:
a first substrate including a first semiconductor layer and a first wiring layer, the first semiconductor layer including a photoelectric conversion element;
a second substrate including a second semiconductor layer and a second wiring layer, the second semiconductor layer including a transistor; and
a through-wire penetrating the second wiring layer, the through-wire extending toward the first wiring layer,
wherein the first substrate is bonded to the second substrate in a structure in which the first wiring layer and the second wiring layer are between the first substrate and the second substrate, and
the through-wire contacts a side surface of a gate or a side surface of a diffusion layer of the transistor, the through-wire is connected to the photoelectric conversion element through a wire of the first substrate.

15. The image sensor of claim 14, wherein
the second semiconductor layer includes a first transistor and a second transistor, and
the through-wire is in contact with a side surface of a diffusion layer of the first transistor and a side surface of a gate of the second transistor.

16. The image sensor of claim 14, wherein the through-wire is connected to the photoelectric conversion element through the wire of the first substrate and a floating diffusion area.

17. The image sensor of claim 14, wherein
the second substrate further includes a metal wire connected to a first surface of the transistor of the second semiconductor layer, the first surface of the transistor opposite a second surface of the transistor that faces the first substrate, and
the metal wire is connected to the through-wire.

18. The image sensor of claim 14, wherein
the second substrate further includes a third wiring layer on the second wiring layer, and
a capacitive element is formed on the third wiring layer.

19. The image sensor of claim 14, further comprising:
a third substrate on the second substrate,
wherein the second substrate is bonded to the third substrate through wiring layers.

20. An image sensor comprising:
a first substrate including a first semiconductor layer and a first wiring layer, the first semiconductor layer including a photoelectric conversion element;
a second substrate including a second semiconductor layer, a second wiring layer, and a third wiring layer, the second wiring layer and the third wiring layer being respectively arranged below and above the second semiconductor layer, the second semiconductor layer including a transistor; and
a third substrate comprising a third semiconductor layer and a fourth wiring layer, the third semiconductor layer including a high functionality circuit,
wherein the first substrate is bonded to the second substrate in a structure in which the first wiring layer and the second wiring layer are between the first substrate and the second substrate,
the second substrate is bonded to the third substrate in a structure in which the third wiring layer and the fourth wiring layer are between the second substrate and the third substrate, and
a through-wire contacts a side surface of a gate or a side surface of a diffusion layer of the transistor, the through-wire penetrates the second substrate, and the through-wire is connected to the photoelectric conversion element through a wire of the first substrate.
